(19) United States
(12) Patent Application Publication
(10) Pub. No.: US 2018/0337070 A1
(43) Pub. Date: Nov. 22, 2018

(54) SUBSTRATE TREATING APPARATUS AND SUBSTRATE TREATING METHOD

(71) Applicant: SEMES CO., LTD., Chungcheongnam-do (KR)

(72) Inventors: Byungsun Bang, Chungcheongnam-do (KR); Buyoung Jung, Chungcheongnam-do (KR); Jungbong Choi, Gyeonggi-do (KR); Bong Joo Kim, Chungcheongnam-do (KR); Youngil Lee, Chungcheongnam-do (KR); Gil Hun Song, Chungcheongnam-do (KR); Gui Su Park, Chungcheongnam-do (KR); Kwang Ryul Kim, Gyeonggi-do (KR); Kwang-Seop Lee, Chungcheongnam-do (KR); Jin Tack Yu, Chungcheongnam-do (KR)

(21) Appl. No.: 15/979,956

(22) Filed: May 15, 2018

(30) Foreign Application Priority Data
May 17, 2017 (KR) 10-2017-0060917

(51) Int. Cl. H01L 21/67; H01L 21/02; B08B 7/00; B08B 3/04; B08B 3/08; B08B 7/04; C03C 23/00; B23K 26/402

(52) U.S. Cl. CPC H01L 21/67028; H01L 21/0206; H01L 21/0217; B08B 7/0042; B23K 26/402; B08B 3/08; B08B 7/04; C03C 23/0025; B08B 3/041

(57) ABSTRACT

Disclosed are a substrate treating apparatus and a substrate treating method. The substrate treating method includes removing a portion of the thin film by irradiating a laser to the substrate, and after the removing of the portion of the thin film, removing the remaining portion of the thin film by supplying a chemical to the substrate.

### CROSS-REFERENCE TO RELATED APPLICATIONS

This application claims priority under 35 U.S.C. § 119 to Korean Patent Application No. 10-2017-0060917 filed on May 17, 2017, in the Korean Intellectual Property Office, the disclosures of which are incorporated by reference herein in their entireties.

### BACKGROUND

Embodiments of the inventive concept described herein relate to a substrate treating apparatus and a substrate treating method.

In order to manufacture a semiconductor device or a liquid crystal display, various processes such as photolithography, etching, ashing, ion implantation, thin film deposition, and cleaning are performed on a substrate. Among them, an etching process is a process of removing an unnecessary area of a thin film formed on a substrate, and requires a high selection ratio and a high etching rate for a thin film.

In general, in a process of etching or cleaning a substrate, a chemical processing operation, a rinsing operation, and a drying operation are sequentially performed. In the chemical processing operation, a thin film formed on a substrate is etched or a chemical for removing foreign substances on a substrate is supplied to a substrate, and in the rinsing operation. A rinsing liquid such as pure water is supplied onto a substrate.

### SUMMARY

Embodiments of the inventive concept provide a substrate treating apparatus that may efficiently treat a substrate, and a substrate treating method.

Embodiments of the inventive concept also provide a substrate treating apparatus that may treat a thin film on a substrate at a high treatment speed and a high selection ratio and a substrate treating method

In accordance with an aspect of the inventive concept, there is provided a substrate treating method including removing a portion of the thin film by irradiating a laser to the substrate, and after the removing of the portion of the thin film, removing the remaining portion of the thin film by supplying a chemical to the substrate.

The thin film may be a silicon nitride.

The laser may include a wavelength of a band of a visual ray.

The laser may include a wavelength of a band of an infrared ray.

In a portion of a zone to which the laser is irradiated, the substrate may be provided to be applied with the chemical.

The substrate may be provided to be rotated when the laser is irradiated, and the laser irradiated to the substrate may be irradiated over a radius area of the substrate via the center of rotation of the substrate.

The substrate may be provided to be rotated when the laser is irradiated, and the laser irradiated to the substrate may be irradiated over a diameter area of the substrate via the center of rotation of the substrate.

The substrate may be provided to be rotated when the laser is irradiated, the laser irradiated to the substrate has a width that is smaller than the radius of the substrate in a radial direction of the substrate and moves in the radial direction of the substrate.

The movement speed of the laser may be lower when the laser is close to an outer edge area than the laser is close to the center of rotation of the substrate.

In accordance with another embodiment of the inventive concept, there is provided a substrate treating apparatus including a housing, a substrate support member located in the interior of the housing and configured to support a substrate, a laser irradiator configured to primarily treat a thin film on the substrate by irradiating a laser to the substrate, and an ejection member configured to secondarily treat a material that resides after the substrate is treated by the laser, by supplying the treatment liquid to the substrate.

The substrate treating apparatus may further include a controller configured to control the substrate support member such that the substrate is rotated when the laser is irradiated, wherein the laser irradiated by the laser irradiator may be irradiated over a radius area of the substrate via the center of rotation of the substrate.

The substrate treating apparatus may further include a controller configured to control the substrate support member such that the substrate is rotated when the laser is irradiated, and the laser irradiated by the laser irradiator may be irradiated over a diameter area of the substrate via the center of rotation of the substrate.

The substrate treating apparatus may further include a controller configured to control the substrate support member such that the substrate is rotated when the laser is irradiated and control the laser irradiator such that the laser irradiated by the laser irradiator moves in a radial direction of the substrate while having a width that is smaller than the radius of the substrate in the radial direction of the substrate.

The controller may control the laser irradiator such that the movement speed of the laser is lower when the laser is close to an outer edge area than the laser is close to the center of rotation of the substrate.

In accordance with another embodiment of the inventive concept, there is provided a substrate treating apparatus including a first process chamber configured to primarily treat a thin film on a substrate by irradiating a laser to the substrate, and a second process chamber configured to secondarily treat a material that resides on the substrate, by supplying a treatment liquid to the substrate that has been treated in the first process chamber.

The process chamber may include a housing, a substrate support member located in the interior of the housing and configured to support a substrate, a laser irradiator configured to primarily treat a thin film on the substrate by irradiating a laser to the substrate, and a controller configured to control the substrate support member such that the substrate is rotated when the laser is irradiated.

The laser irradiated to the substrate may be linearly provided.

The laser may be irradiated via the center of rotation of the substrate.

The thin film may be a silicon nitride and the treatment liquid is a phosphoric acid.

The laser may include a wavelength of bands of a visual ray and an infrared ray.

### BRIEF DESCRIPTION OF THE FIGURES

The above and other objects and features of the inventive concept will become apparent by describing in detail exemplary embodiments thereof with reference to the accompanying drawings.

FIG. 1 is a view illustrating a substrate treating apparatus according to an embodiment of the inventive concept;

FIG. 2 is a view illustrating a first process chamber provided in a treatment unit;

FIG. 3 is a view illustrating a piping relationship of an ejection member;

FIG. 4 is a view illustrating a process of treating a substrate;

FIG. 5 is a view illustrating a laser irradiated to a substrate according to an example;

FIG. 6 is a view illustrating a laser irradiated according to another embodiment of the inventive concept; and

FIG. 7 is a view illustrating a second process chamber provided in a treatment unit.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited to the following embodiments. The embodiments of the inventive concept are provided to describe the inventive concept for those skilled in the art more completely. Accordingly, the shapes of the components of the drawings are exaggerated to emphasize clearer description thereof.

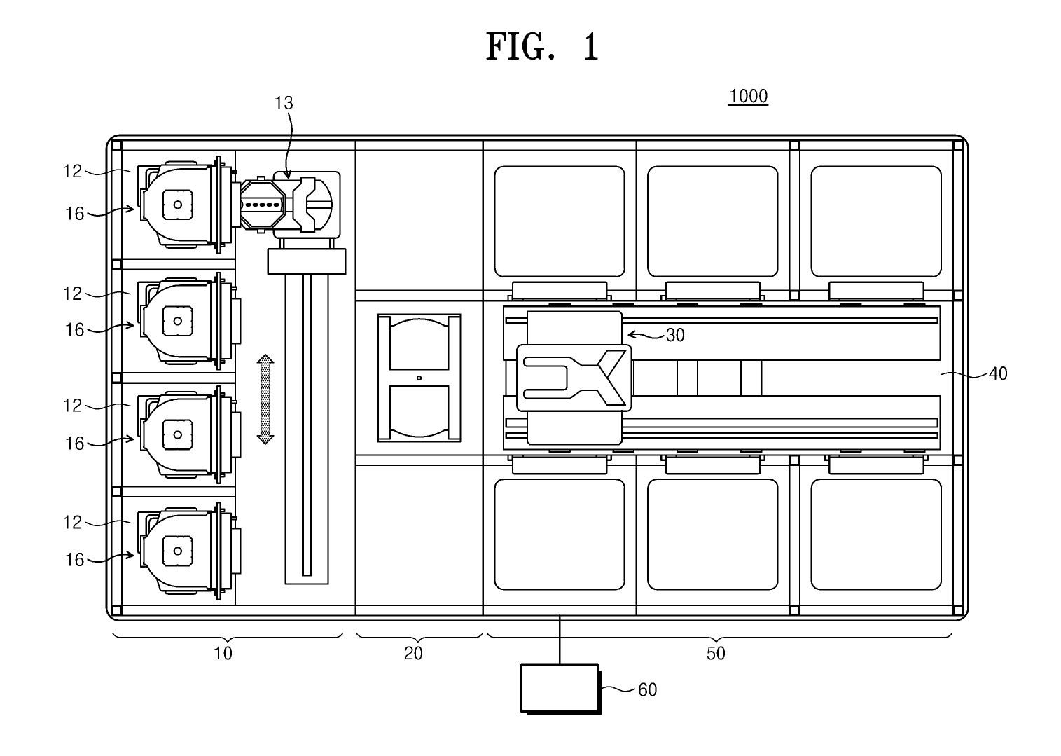

FIG. 1 is a view illustrating a substrate treating apparatus according to an embodiment of the inventive concept.

Referring to FIG. 1, the substrate treating system 1000 according to the inventive concept may include an index unit 10, a buffer unit 20, a treatment unit 50, and a controller 60. The index unit 10, the buffer unit 20, and the treatment unit 50 may be disposed in a row. Hereinafter, a direction in which the index unit 10, the buffer unit 20, and the treatment unit 50 are arranged is referred to as a first direction, a direction that is perpendicular to the first direction when viewed from the top is referred to as a second direction, and a direction that is perpendicular to a plane including the first direction and the second direction is referred to as a third direction.

The index unit 10 is disposed in front of the substrate treating apparatus 1000 in the first direction 1. The index unit 10 includes four load ports 12 and one index robot 13.

The four load ports 12 are disposed in front of the index unit 10 in the first direction. A plurality of load ports 12 are provided, and are disposed along the second direction 2. However, the number of the load ports 12 may be changed according to the process efficiency of the process treating system 1000 or a footprint condition. Substrates W that are to be provided in a process and carriers (for example, cassettes or FOUPs) in which completely processed substrates W are located in the load ports 12. A plurality of slots for receiving substrates W while the substrates W are arranged in parallel to the ground surface are formed in the carrier 16.

The index robot 13 is disposed adjacent to the load ports 12 in the first direction. The index robot 13 is disposed between the load ports 12 and the buffer unit 20. The index robot 13 feeds a substrate W that stands by on an upper layer of the buffer unit 20 to a carrier 16 or feeds a substrate W that stands by in the carrier 16 to a lower layer of the buffer unit 20.

The buffer unit 20 is located between the index unit 10 and the treatment unit 50. The buffer unit 20 is a site at which a substrate W that is to be provided to a process before being fed by the index robot 13 or a substrate W that is completely processed before being fed by a main feeding robot 30 is temporarily received and stands by.

The main feeding robot 30 is located in the feeding chamber 40, and feeds substrates W between the process chambers and the buffer unit 20. The main feeding robot 30 feeds substrates W that are to be provided to a process of standing by in the buffer unit 20 or feeds substrates W that are completely processed in the process chambers to the buffer unit 20.

The feeding chamber 40 is disposed along a first direction of the treatment unit and provides a passage, through which the main feeding robot 30 moves. Process chambers are disposed on opposite sides of the feeding chamber 40 along the first direction while facing each other. A movement rail on which the main feeding robot 30 moves along the first direction and by which the main feeding robot 30 elevates to upper and lower layers of the process chamber and upper and lower layers of the buffer unit 20 is installed in the feeding chamber 40.

The process chamber is disposed on opposite sides or one side of the feeding chamber 40 to be adjacent to the feeding chamber 40 in which the main feeding robot 30 is installed. The substrate treating apparatus 1000 includes a plurality of process chambers having upper and lower layers, but the number of the process chambers may be increased or decreased according to process efficiency and a footprint condition of the substrate treating apparatus 1000. Each of the process chambers includes an independent housing 800, and accordingly, a process of treating a substrate W in an independent form may be performed in each of the substrate treating apparatuses.

The controller 60 controls the components of the substrate treating apparatus 1000. Further, the controller 60 may control the elements of the process chamber.

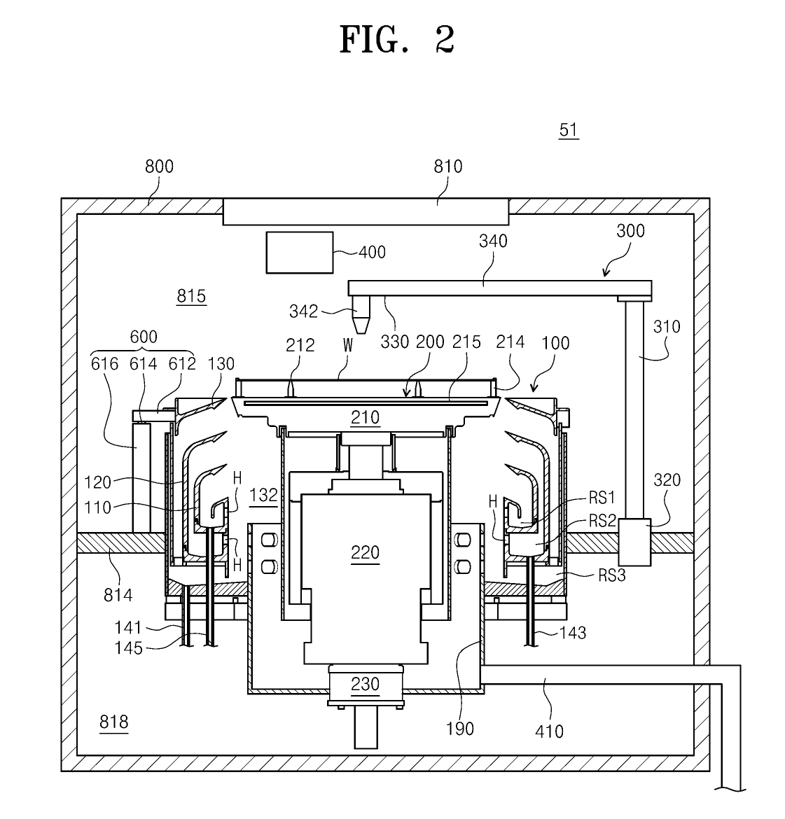

FIG. 2 is a view illustrating a first process chamber 51 provided in a treatment unit.

A semiconductor wafer has been illustrated and described in the embodiment as a substrate W that is treated by the first process chamber 51 provided in the treatment unit 50, but the inventive concept is not limited thereto and various substrates W such as a glass substrate W may be applied.

Referring to FIG. 2, the first process chamber 51 according to the inventive concept includes a housing 800, a treatment container 100, a substrate support member 200, an ejection member 300, a laser irradiator 400, and an exhaust line 410.

The housing 800 provides a sealed interior space. The housing 800 may be partitioned into a process area 815 and a maintenance area 818 by a partition wall 814. Although only some parts of the maintenance area are illustrated in the drawings, the maintenance area 818 is a space in which discharge lines 141, 143, and 145 connected to the treatment container 100 and an exhaust line 410 are located, and it is preferable that the maintenance area 818 be isolated from the process area in which a substrate W is treated.

The treatment container 100 has an open-topped vessel shape, and provides a process space for treating the substrate W. The opened upper surface of the treatment container 100 is provided as a carrying-in/out passage of the substrate W. The substrate support member 200 is located in the process space. During the process, the substrate support member 200 supports the substrate W and rotates the substrate W.

First, second, and third annular suction ducts 110, 120, and 130 for introducing and suctioning the chemicals spattering on the rotating substrate W and gases are disposed in multiple stages are disposed on the upper side of the treatment container 100. Each of the first, second, and third annular suction ducts 110, 120, and 130 has an exhaust hole H communicating with one common annular space (corresponding to a lower space of the container). An exhaust duct 190 connected to the exhaustion member 400 is provided below the treatment container 100.

In detail, each of the first to third suction ducts 110, 120, and 130 includes a bottom surface having an annular ring shape, and a side wall extending from the bottom surface and having a cylindrical shape. The second suction duct 120 surrounds the first suction duct 110, and is spaced apart from the first suction duct 110. The third suction duct 130 surrounds the second suction duct 120, and is spaced apart from the second suction duct 120.

The first to third suction ducts 110, 120, and 130 provide first to third recovery spaces RS1, RS2, and RS3 into which the treatment liquid spattering from the substrate W and the gas flows containing fumes are introduced. The first recovery space RS1 is defined by the first suction duct 110, the second recovery space RS2 is defined by a space between the first suction duct 110 and the second suction duct 120, and the third recovery space RS3 is defined by a space between the second suction duct 120 and the third suction duct 130.

The centers of the upper surfaces of the first to third suction ducts 110, 120, and 130 are opened, and have an inclined surface a distance from the bottom surface of which gradually increases as it goes from the side wall towards the opening. Accordingly, the treatment liquid spattering from the substrate W flows into the recovery spaces RS1, RS2, and RS3 along the upper surfaces of the first to third suction ducts 110, 120, and 130.

The first treatment liquid introduced into the first recovery space RS1 is discharged to the outside through the first recovery line 141. The second treatment liquid introduced into the second recovery space RS2 is discharged to the outside through the second recovery line 143. The third treatment liquid introduced into the third recovery space RS3 is discharged to the outside through the third recovery line 145.

Meanwhile, the treatment container 100 is coupled to the elevation unit 600 that changes a vertical location of the treatment container 100. The elevation unit 600 linearly moves the container 100 upwards and downwards. When the container 100 is moved upwards and downwards, a relative height of the container 100 to the spin head 210 is changed.

The elevation unit 600 has a bracket 612, a movable shaft 614, and a driver 616. The bracket 612 is installed on an outer wall of the container 100, and the movable shaft 614 that is moved upwards and downwards by the driver 616 is fixedly coupled to the bracket 612. The treatment container 100 is lowered such that, when the substrate W is loaded on the spin head 210 or is unloaded from the spin head 210, the spin head 210 protrudes to the upper side of the treatment container 100. When the process is performed, the height of the container 100 is adjusted such that the treatment liquid is introduced into the suction ducts 110, 120, and 130 according to the kind of the treatment liquid supplied to the substrate W. Accordingly, a relative vertical location between the treatment container 100 and the substrate W is changed. Accordingly, the treatment container 100 may make the kinds of the treatment liquids and the contaminated gases recovered for the recovery spaces RS1, RS2, and RS3 different.

In the embodiment, the first process chamber 51 vertically moves the treatment container 100 to change a relative vertical location between the treatment container 100 and the substrate support member 200. However, the first process chamber 51 may vertically move the substrate support member 200 to change a relative vertical location between the treatment container 100 and the substrate support member 200.

The substrate support member 200 is installed inside the treatment container 100. The substrate support member 200 may support the substrate W during the process, and may be rotated by the driver 230, which will be described below, during the process. The substrate support member 200 has a spin head 210 having a circular upper surface, and support pins 212 supporting the substrate W and chucking pins 214 may be provided on an upper surface of the spin head 210. The support pins 212 are disposed in a specific array at a periphery of the upper surface of the spin head 210 to be spaced apart from each other, and protrude from the spin head 210 upwards. The support pins 212 supports the lower surface of the substrate W such that the substrate W is supported while being spaced upwards apart from the spin head 210. The chucking pins 214 are disposed on the outside of the support pins 212, and protrude upwards. The chucking pins 214 arrange the substrate W such that the substrate W supported by a plurality of support pins 212 may be positioned at a right location on the spin head 210. During the process, the chucking pins 214 contact a side of the substrate W to prevent the substrate W from deviating from the proper location. The spin head 210 may be provided with a heater 215 for heating a rinsing liquid supplied to the substrate W.

The support shaft 220 supporting the spin head 210 is connected to a lower side of the spin head 210, and the support shaft 220 is rotated by the driver 230 connected to a lower end thereof. The driver 230 may be a motor or the like. As the support shaft 220 is rotated, the spin head 210 and the substrate W are rotated.

The ejection member 300 is supplied with the treatment liquid during the substrate treating process and ejects the treatment liquid to a treatment surface of the substrate W positioned on the spin head 210 of the substrate support member 200. The ejection member 300 includes a support shaft 310, a driver 320, a nozzle support 340, and an ejection nozzle 342.

A lengthwise direction of the support shaft 310 is a vertical direction, and a lower end of the support shaft 310 is coupled to the driver 320. The driver 320 changes a location of the support shaft 310 or rotates the support shaft 310. The nozzle support 340 is coupled to the support shaft 310 to move the ejection nozzle 342 to an upper side of the substrate W or to move the ejection nozzle 342 while the ejection nozzle 342 ejects the treatment liquid above the substrate W.

The ejection nozzle 342 is installed on the bottom surface of an end of the nozzle support 340. The ejection nozzle 342 is moved to a process location and a standby location by the driver 320. The process location defined as a location at which the ejection nozzle 342 is disposed at a vertical upper portion of the treatment container 100, and the standby location is a location at which the ejection nozzle 342 deviates from the vertical upper portion of the treatment container 100. The ejection nozzle 342 ejects the treatment liquid. Then, the treatment liquid supplied to the substrate W may be a chemical for cleaning a substrate W or a chemical for etching a substrate W.

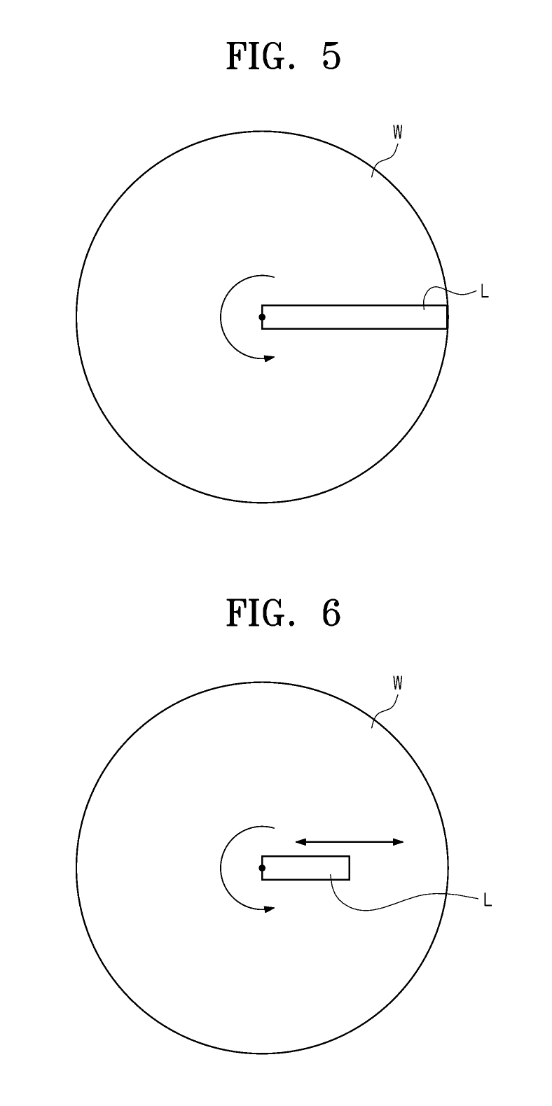

The laser irradiator 400 treats the substrate W by irradiating a laser L (see FIG. 5) to the substrate W. A location of a lower side of the laser irradiator 400, from which the laser L is irradiated, may be adjusted such that the location of the laser L irradiated to the substrate W may vary. As an example, the laser irradiator 400 may be provided such that the location of the laser irradiator 400 may be adjusted while being supported by a load, similarly to the ejection member. Further, the laser irradiator 400 may be provided such that the direction of the laser L irradiated to the substrate W may be adjusted while the laser irradiator 400 is located on an upper wall or a side wall of the housing 800. The laser irradiator 400 may irradiate a laser L having a wavelength of a band of a visual ray. The laser irradiator 400 may irradiate a laser L having a wavelength of a band of an infrared ray. The laser irradiator 400 may irradiate a laser L having a wavelength of bands of a visual ray and an infrared ray.

The exhaust line 410 discharges a gas in the treatment container 100. A fan filter unit 810 that supplies a gas for forming lower gas flows in an interior space of the housing 800 may be located above the housing 800.

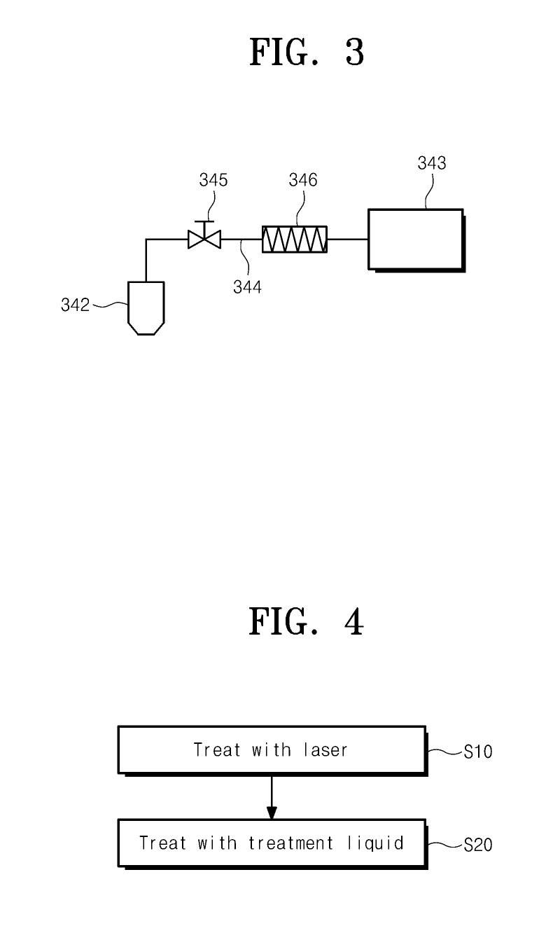

FIG. 3 is a view illustrating a piping relationship of an ejection nozzle.

Referring to FIG. 3, the ejection nozzle 342 is connected to a treatment liquid tank 343 through a supply pipeline 344. A valve 345 may be located in the treatment liquid tank 343. The supply pipeline 344 may supply the treatment liquid to the ejection nozzle 342 while being heated at a preset temperature. As an example, a pipeline heater 346 may be located in the supply pipeline 344. Accordingly, the treatment liquid may be heated to a preset temperature by the pipeline heater 346 in a process of supplying the treatment liquid through the supply pipeline 344. Further, the treatment liquid tank 343 may supply the treatment liquid to the supply pipeline 344 after the treatment liquid is heated to a preset temperature. Further, the treatment liquid tank 343 may supply the treatment liquid to the supply pipe line 344 after the treatment liquid is heated to the preset temperature, and may prevent the temperature of the treatment liquid from decreasing in the process of supplying rinsing liquid, with the pipeline heater 346.

FIG. 4 is a view illustrating a process of treating a substrate. FIG. 5 is a view illustrating a laser irradiated to a substrate according to an example.

Referring to FIGS. 4 and 5, the substrate W is primarily treated through a laser L. As an example, the laser L may primarily treat a thin film on the substrate W at a high speed. The laser irradiator 400 irradiates the laser L to an upper surface of the substrate W. The controller 60 may control the substrate support member 200 such that the substrate is rotated when the laser L is irradiated.

The laser L irradiated onto the upper surface of the substrate W may be linearly provided. The laser L irradiated to the substrate W may pass through the center of rotation of the substrate W. As an example, the laser L irradiated to the substrate W may be linearly provided, and may be irradiated to an area corresponding to the radius of the substrate W while having a preset width over an outer end of the substrate W from the center of rotation of the substrate W. Accordingly, as the substrate W rotates, the laser L may be irradiated over an entire area of the upper surface of the substrate W. As another example, the laser L irradiated to the substrate W may be linearly provided, and may be irradiated to an area corresponding to the diameter of the substrate W while having a preset width such that opposite ends of the laser L are located at an outer end of the substrate W and the laser L passes through the center of rotation of the substrate W. As the laser L is irradiated, the substrate W is primarily treated by the energy provided by the laser L. When the substrate W is primarily treated, the substrate W may be additionally supplied with the treatment liquid by the ejection member. The supply of the treatment liquid may be initiated prior to the irradiation of the laser L by a preset time. Further, the supply of the treatment liquid may be initiated at the same time when the laser L is irradiated. Further, the supply of the treatment liquid may be irradiated after a preset time elapses from the irradiation of the laser L. Accordingly, the irradiation of the laser L and the supply of the treatment liquid may be performed together for a preset period of time. The supply of the treatment liquid may be stopped prior to the irradiation of the laser L by a preset time. Further, the supply of the treatment liquid may be stopped at the same time when the irradiation of the laser L is stopped. Further, the supply of the treatment liquid may be stopped after a lapse of a preset time from the stop of the irradiation of the laser L. As an example, the material on the substrate W treated by the laser L may be a thin film of a silicon nitride. The treatment liquid supplied to the substrate W may be a phosphoric acid.

According to an embodiment of the inventive concept, the substrate W may be primarily treated at a high speed through the laser, or the laser and the treatment liquid.

FIG. 6 is a view illustrating a laser irradiated according to another embodiment of the inventive concept.

Referring to FIG. 6, the laser L irradiated to the substrate W may be provided such that the radial width of the substrate W is smaller than the radius of the substrate W. The controller 60 may control the laser irradiator 400 such that the laser L irradiated to the substrate W reciprocates between the center of rotation and an outer edge of the substrate W one or more times. As the substrate W rotates while the laser L is irradiated, the laser L may be irradiated over the entire upper surface of the substrate W. The movement speed of the laser L may be different along the radial direction of the substrate W from the center of rotation of the substrate W. The movement speed of the laser L may be lower when the laser is close to the outer edge of the substrate than when the laser is close to the center of rotation of the substrate W. As an example, the movement speed of the laser L may become lower in proportion to the radial distance of the substrate W with respect to the center of rotation of the substrate W. Accordingly, the residing time of the laser L may increase in an area in which the circumference of the area to which the laser L is irradiated is large.

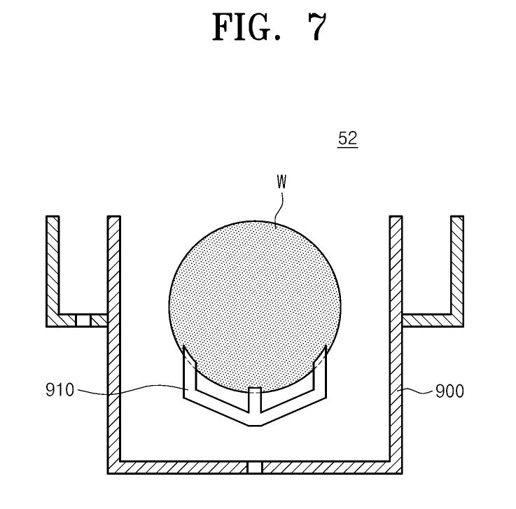

FIG. 7 is a view illustrating a second process chamber provided in a treatment unit.

Referring to FIG. 7, the second process chamber 52 includes a treatment vessel 900 and a support member 910. The treatment vessel 900 may have a container shape in which a space of a preset volume, which accommodates the treatment liquid, is formed therein. The support member 910 supports the substrate W while the substrate W is treated inside the treatment vessel 900. The support member 910 may be provided in a form capable of supporting a plurality of substrates W.

After the substrate W is primarily treated by the laser L in the first process chamber 51, the substrate W is fed to the second process chamber 52 and is secondarily treated by the treatment liquid. At this time, the treatment liquid that treats the substrate W in the second process chamber 52 may be in a state in which an additive is added to the treatment liquid used in the first process chamber 51. The additive may be a composite containing silicon (Si). Further, the treatment liquid may contain an auxiliary additive. The auxiliary additive may be an inhibitor that assists dispersion of an additive that is a silicon composite. If the additive or the additive and the auxiliary additive are added to the treatment liquid, a selection ratio or the treatment of the substrate by the treatment may be improved.

According to an embodiment of the inventive concept, the substrate primarily treated at a high speed may have a high selection ratio through the treatment liquid or the treatment liquid containing the additive, and the treatment target residing in the substrate W may be secondarily treated.

As another embodiment, the primary treatment by the laser L and the secondary treatment by the treatment may be performed in one process chamber. For example, after primarily treating the substrate W through the laser irradiator 400, the first process chamber 51 may secondarily supply the substrate W by supplying the treatment liquid with the ejection member.

According to an embodiment of the inventive concept, a substrate treating apparatus that efficiently treats a substrate and a substrate treating method may be provided.

Further, according to an embodiment of the inventive concept, a substrate treating apparatus that may treat a thin film on a substrate at a high treatment speed and a high selection ratio and a substrate treating method may be provided.

The above description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A substrate treating method comprising:
removing a portion of the thin film by irradiating a laser to the substrate; and
after the removing of the portion of the thin film, removing the remaining portion of the thin film by supplying a chemical to the substrate.

2. The substrate treating method of claim 1, wherein the thin film is a silicon nitride.

3. The substrate treating method of claim 1, wherein the laser includes a wavelength of a band of a visual ray.

4. The substrate treating method of claim 1, wherein the laser includes a wavelength of a band of an infrared ray.

5. The substrate treating method of claim 1, wherein in a portion of a zone to which the laser is irradiated, the substrate is provided to be applied with the chemical.

6. The substrate treating method of claim 1, wherein the substrate is provided to be rotated when the laser is irradiated, and the laser irradiated to the substrate is irradiated over a radius area of the substrate via the center of rotation of the substrate.

7. The substrate treating method of claim 1, wherein the substrate is provided to be rotated when the laser is irradiated, and the laser irradiated to the substrate is irradiated over a diameter area of the substrate via the center of rotation of the substrate.

8. The substrate treating method of claim 1, wherein the substrate is provided to be rotated when the laser is irradiated, the laser irradiated to the substrate has a width that is smaller than the radius of the substrate in a radial direction of the substrate and moves in the radial direction of the substrate.

9. The substrate treating method of claim 8, wherein the movement speed of the laser is lower when the laser is close to an outer edge area than the laser is close to the center of rotation of the substrate.

10. A substrate treating apparatus comprising:
a housing;
a substrate support member located in the interior of the housing and configured to support a substrate;
a laser irradiator configured to primarily treat a thin film on the substrate by irradiating a laser to the substrate; and
an ejection member configured to secondarily treat a material that resides after the substrate is treated by the laser, by supplying the treatment liquid to the substrate.

11. The substrate treating apparatus of claim 10, further comprising:
a controller configured to control the substrate support member such that the substrate is rotated when the laser is irradiated,
wherein the laser irradiated by the laser irradiator is irradiated over a radius area of the substrate via the center of rotation of the substrate.

12. The substrate treating apparatus of claim 10, further comprising:
a controller configured to control the substrate support member such that the substrate is rotated when the laser is irradiated,
wherein the laser irradiated by the laser irradiator is irradiated over a diameter area of the substrate via the center of rotation of the substrate.

13. The substrate treating apparatus of claim 10, further comprising:
a controller configured to control the substrate support member such that the substrate is rotated when the laser is irradiated and control the laser irradiator such that the laser irradiated by the laser irradiator moves in a radial direction of the substrate while having a width that is smaller than the radius of the substrate in the radial direction of the substrate.

14. The substrate treating apparatus of claim 13, wherein the controller controls the laser irradiator such that the movement speed of the laser is lower when the laser is close to an outer edge area than the laser is close to the center of rotation of the substrate.

15. A substrate treating apparatus comprising:
a first process chamber configured to primarily treat a thin film on a substrate by irradiating a laser to the substrate; and
a second process chamber configured to secondarily treat a material that resides on the substrate, by supplying a treatment liquid to the substrate that has been treated in the first process chamber.

16. The substrate treating apparatus of claim 15, wherein the process chamber includes:
a housing;
a substrate support member located in the interior of the housing and configured to support a substrate;
a laser irradiator configured to primarily treat a thin film on the substrate by irradiating a laser to the substrate; and
a controller configured to control the substrate support member such that the substrate is rotated when the laser is irradiated.

17. The substrate treating apparatus of claim 16, wherein the laser irradiated to the substrate is linearly provided.

18. The substrate treating apparatus of claim 17, wherein the laser is irradiated via the center of rotation of the substrate.

19. The substrate treating apparatus of claim 15, wherein the thin film is a silicon nitride and the treatment liquid is a phosphoric acid.

20. The substrate treating apparatus of claim 15, wherein the laser includes a wavelength of bands of a visual ray and an infrared ray.
